(19) United States
(12) Patent Application Publication
(10) Pub. No.: US 2007/0001223 A1
(43) Pub. Date: Jan. 4, 2007

(54) Ultrathin-body schottky contact MOSFET

(76) Inventors: Diane C. Boyd, Lagrangeville, NY (US); Meikei Leong, Wappingers Falls, NY (US); Jakub Tadeusz Kedzierski, Waltham, MA (US); Ghavam G. Shahidi, Pound Ridge, NY (US)

Correspondence Address: INNOVATION INTERFACE, LLC, 303 TABER AVENUE, PROVIDENCE, RI, 02906, US

(21) Appl. No.: 11/172,711

(22) Filed: Jul. 1, 2005

(51) Int. Cl. H01L 27/12

(52) U.S. Cl. 257/347

(57) ABSTRACT

An ultra thin SOI MOSFET device structure and method of fabrication is presented. The device has a terminal composed of silicide, which terminal is forming a Schottky contact with the channel. A plurality of impurities are segregated on the silicide/channel interface, and these segregated impurities determine the resistance of the Schottky contact. Such impurity segregation is achieved by a so called silicidation induced impurity segregation process. Silicon substitutional impurities are appropriate for accomplishing such a segregation.

### FIELD OF THE INVENTION

The present invention relates to the field of integrated circuits and their manufacturing. More particularly, the present invention relates to the structure of high performance silicon on insulator (SOI) field effect devices.

### BACKGROUND OF THE INVENTION

Today's integrated circuits include a vast number of devices. Silicon (Si), or more broadly, Si based materials such as SiGe, are the primary materials of the microelectronics arts. Smaller devices are key to enhance performance and to improve reliability. As MOSFET (Metal Oxide Semiconductor Field-Effect-Transistor, a name with historic connotations meaning in general an insulated gate Field-Effect-Transistor) devices are being scaled down, the technology becomes more complex. There is great difficulty in maintaining performance improvements in devices of deeply submicron generations.

A whole microelectronics art has been developed in designing and manufacturing MOSFET devices in so called silicon-on-insulator (SOI) technology. This technology is thought to be able to extend the miniaturization of devices. The SOI technology is developing toward ultra thin (UT) semiconductor layers with fully depleted (FD) bodies. Such FD-UT SOI MOSFET devices promise some of the highest performing microelectronics technologies.

As all MOSFETs, SOI devices have a common structure, well known in the art. A device body is adjoined by current carrying terminals, a source terminal, or source for brevity, and a drain terminal, or drain for brevity. On the surface of the device body a conducting channel can be induced by a gate electrode. The gate is typically electrically insulated from the body by a gate dielectric. The channel is capable to electrically connect the current terminals of the source and the drain.

One of the principal challenges in ultra thin SOI technology is the achievement of low parasitic resistance arising from the terminals of the device. Due to the fact that the Si layer on top of the insulator is thin, terminal resistances, such as the so called extension resistance, and the contact resistance tend to be high. The extension resistance tends to be high because the extension is shallower than it would be in a bulk transistor, and the contact resistance tends to be high because there is only a small surface area that serves as the boundary between a metal contacting the device and the semiconductor.

A process does exists to increase the surface area of the metal semiconductor boundary and thus decrease the contact resistance. This process is called raised source/drain (RSD) fabrication. Unfortunately, the RSD process is an imperfect solution, it decreases device performance in unintended ways unrelated to parasitic resistance, and it is a difficult and costly process to integrate into manufacturing. Also, as far as parasitic resistance reduction, it leaves much to desire, since among other disadvantages it does not address the resistance of the source/drain extension. A solution which would decrease terminal resistance without the complexity and the disadvantages of the RSD technology, would be very desirable.

### SUMMARY OF THE INVENTION

In view of the problems discussed above this invention discloses a low resistance Schottky contact for SOI MOSFET devices.

A MOSFET device is disclosed which comprises a body composed of a crystalline Si based material, and which body is disposed over an insulator and it is hosting the channel of the device. A terminal of the MOSFET is composed of a silicide material, and the terminal forms a Schottky contact with the channel. The silicide material of the terminal also interfaces with the insulator, excluding the crystalline Si based material of the body between the terminal and the insulator. The silicide material and the body interface accommodates a plurality of segregated impurities, which segregated impurities determine the resistance of the Schottky contact. The segregated impurities are typically silicon substitutional impurities. The device may have its other terminal also formed of a silicide material. Typically both terminals, the source and the drain, would be composed of the same silicide material. In representative embodiments the silicon based material of the body may essentially be Si. Typically, the body is so designed to be in a fully depleted state.

A method for fabricating the MOSFET device comprises the steps of providing a layer composed of a crystalline Si based material disposed over an insulator, and then forming the device body in this layer. The body is hosting the channel of the device. A terminal-region is defined in the layer, and impurities are introduced in this terminal-region. The terminal is then formed by converting essentially all of the Si based material of the layer in the terminal-region into a silicide material. In this manner an interface is being created between the terminal and the body, and a Schottky contact is formed at the interface between the channel and the terminal. A fraction of the impurities introduced into the terminal-region will segregate onto this interface, and will be determining the resistance of the Schottky contact. The method may further involve the formation of the other terminal comprising a silicide material, which silicide material typically may be the same kind for both terminals. In representative embodiments the silicon based material of the body may be chosen to be essentially Si. The parameters of the MOSFET are so chosen that the body of the device is typically in a fully depleted state.

### BRIEF DESCRIPTION OF THE DRAWINGS

These and other features of the present invention will become apparent from the accompanying detailed description and drawings, wherein:

FIG. 1 shows for a SOI MOSFET device a schematic cross sectional view of a Schottky contact formed between a terminal composed of silicide material and the channel, and shows the impurity segregation on this interface;

FIG. 2 shows a schematic cross sectional view of a SOI MOSFET device with Schottky contacts to the channel, and shows the impurity segregation;

FIGS. 3A-3D schematically show a series of steps in the method of forming a Schottky contact SOI MOSFET; and

FIG. 4 shows symbolically a processor which contains a MOSFET device with a Schottky contact between a silicided terminal and the channel, and having a plurality of segregated impurities on the terminal/semiconductor interface.

### DETAILED DESCRIPTION OF THE INVENTION

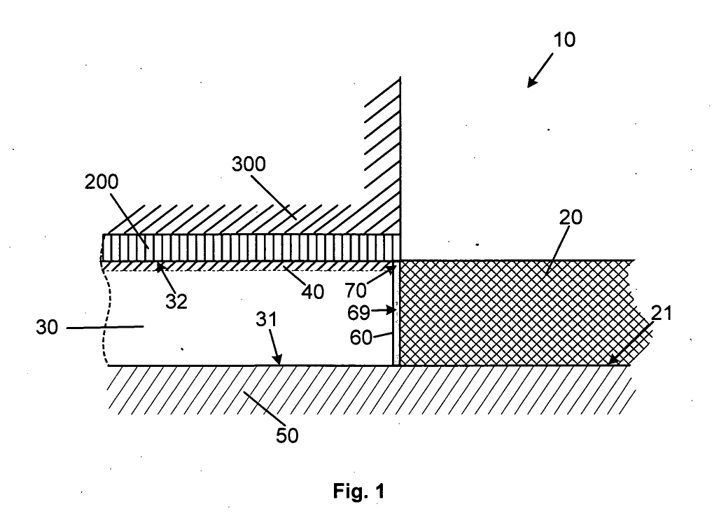

FIG. 1 shows for a SOI MOSFET device 10 a schematic cross sectional view of a Schottky contact formed between a terminal 20 composed of silicide material and the channel 40, and shows the impurity segregation 60 on this interface. The term first terminal can mean either the source or the drain. For embodiments where the first terminal is the source terminal, the term second terminal refers to the drain terminal. Conversely, in embodiments where the first terminal would be the drain terminal, the term second terminal refers to the source terminal.

In an exemplary embodiment the SOI MOSFET device of FIG. 1 is an ultra thin (UT) SOI device with a fully depleted (FD) body, a FD-UT SOI MOSFET. The body 30 of the device is disposed over an insulator 50. In a representative embodiment the insulator 50 is a so called buried oxide (BOX) layer, SiO₂ located on a supporting substrate, typically Si. However, the insulator 50 can be other than SiO₂, for instance, a so called high-k material, or any other insulator known in the art and used for such purposes. Typically the insulator 50 is a layer disposed over a substrate, usually a Si substrate. The body 30 of the device is a thin layer of crystalline material disposed over the insulator 50. In a typical embodiment, the body 30 is made of a Si based material. The primary semiconducting material of microelectronics is silicon (Si), which depending on various needs may be alloyed with other elements such as Ge, forming SiGe, or for instance with C. Such Si alloys are collectively called silicon based materials. In some embodiments of the invention the body 30 may contain up to about 99% of Ge. In a typical embodiment the body 30 is essentially pure Si. The dimensions of the body in representative embodiments follow from the requirements of high performance, as. it is known in the art. In advanced technologies device body lengths, which are typically also the lengths of the gates, are shrinking to less than 100 nm. The thickness of the body layer 30 in exemplary embodiments is even less than the body length. Accordingly, in a typical embodiment the length, namely the distance between the source and the drain, of the body 30 in the fully depleted ultra thin SOI MOSFET device may be between about 5 nm and 200 nm, and the body 30 layer thickness may be between about 1.5 nm and 120 nm. The body 30 in an exemplary embodiment is so designed that it is fully depleted of majority carriers, that is, of electrons for N-MOS devices, and holes for P-MOS devices. The advantages of ultra thin SOI are known in the arts, and are given, for instance, in such publications as: R. Chau et al., “A 50 nm Depleted-Substrate CMOS Transistor (DST), IEDM 2001, p. 621-624, (2001), and J. Kedzierski et al., “Issues in NiSi-gated FDSOI device integration”, IEDM 2003, p. 441-444 (2003).

The body 30 layer has two opposite sides: a top side 32, and a bottom side 31. The bottom side is interfacing with the insulator 50. The body is hosting the channel 40 of the device extending from the top side 32 of the body. As it is standard for MOS devices, the body is overlaid by a gate insulator 200, which separates the gate 300 from the body 30. Depending whether the MOS device is n-type or p-type, the channel carriers are electrons or holes, respectively.

In representative embodiments of the invention, the first terminal 20 is composed of a first silicide material, a metallic compound. Silicide materials are well known in the art. There is a large number of such silicide materials; a non-exhausting list may include nickel silicide, cobalt silicide, palladium silicide, platinum silicide, titanium silicide, and their mixtures, but many more are known and may serve as a first silicide material for first terminal 20. The first silicide material of the first terminal 20 in an exemplary embodiment of the invention forms an interface 69 with the body 30. The first silicide material of the first terminal 20 also interfaces with the surface 21 the insulator 50, and whereby it is excluding the crystalline Si based material of the body 30 between the first terminal 20 and the insulator 50. Such terminals that penetrate down to the insulator on which the device is disposed on, are known in the art and are typical for fully depleted-ultra thin SOI MOSFET devices.

In MOS devices there is a need for an electrical contact between the terminal and the channel. For high performance devices it is desirable for this contact to pose as little resistance as possible against the flow of charge carriers. In an exemplary embodiment of the present invention the channel 40 is contacted 70 directly by the first silicide material of the first terminal 20. This occurs where the first terminal to body interface 69 intersects the channel 40, near the top surface 32 of the body. In the electronics arts siliciding one, or both terminals is well know, however, almost exclusively the silicide of the terminal does not penetrate all the way to the channel. In the standard art the channel is contacted by a doped extension of the silicided part of the terminal, forming a semiconductor to semiconductor contact. The present invention does not use such an extension, and does away with the resistance associated with it.

The direct contact 70 between a metallic material, such as the first silicide material of the first terminal 20, and a semiconductor, such as the channel 40, is called a Schottky contact. A “Schottky contact” or as also known a “Schottky-barrier contact” is simply a nomenclature for a metal-semiconductor contact. As background information applicant refers to pages 245, 491, and 492 from “Sze”, one of the basic reference books on semiconductors (Simon Sze: “Physics of Semiconductor Devices”, (1981) John Wiley and Sons, Second Edition ISBN 0-471-05661-8). Page 245 of Sze underlines that after the work of Schottky, semiconductor to metal contacts are referred to as Schottky-barrier contacts. Pages 491 and 492 of Sze explain the prior art of a metallic source/drain forming a Schottky-barrier contact with the channel. For more recent work and inventions, and for additional background on Schottky source and drain contact, reference is made to a paper entitled: “New Complimentary Metal-Oxide Semiconductor Technology with Self-Aligned Schottky source/drain and Low-Resistance T Gates” by S. A. Rishton, et al, J. Vac. Sci. Tech. B 15 (6), 1997, pp. 2795-2798, and applicant herein incorporates by reference U.S. patent application Ser. No. 10/427,233, filed May 01, 2003, (publication 20040217430), on “High performance FET devices and methods thereof” by J. Chu. None of these works, however, teach the present invention.

A Schottky contact has a resistance. This resistance depends on both the semiconductor and the metal. Such dependancies are due to an energy barrier between the two materials, and to doping of the semiconductor. The height of the energy barrier between the semiconductor and metal depends on an effective workfunction of the metal at the interface with the semiconductor. It has been recently observed that this effective workfunction depends on a layer of impurities that can be made to segregate onto the Schottky contact interface. Regarding such recent observations reference is made to the following publication: Jakub Kedzierski et al, “Threshold voltage control in NiSi-gated MOSFETs through silicidation induced impurity segregation (SIIS)”, IEEE Transaction on Electron Devices, 2005, and U.S. patent application Ser. No. 10/669898, (US patent publication 20050064636) filed Sep. 24, 2003 by Cabral et al. It has also been observed, that certain impurities in Si based materials, and specifically in Si itself, segregate out onto the silicide interface during the silicidation process, as the silicide front consumes the semiconductor. Silicidation processes themselves are well know and routinely performed in the microelectronics arts, however the impurity segregation, and the determining effect of impurities on the effective workfunction, is novel. This segregation and workfunction influencing effect has been described, and its use for a MOS gate fabrication process demonstrated in U.S. patent application Ser. No. 10/669898, filed Sep. 24, 2003, (US patent publication 20050064636) “Method and apparatus for fabricating CMOS field effect transistors” of C. Cabral et al, incorporated herein by reference.

In FIG. 1, for sake of visibility, the interface impurities are indicated by region 60, although in reality these impurities are probably forming a less than full monolayer on the interface 69 between the first silicide material of the first terminal 20 and the body 30. Thus, the impurities have no practical physical volume associated with them in the MOSFET device. In a representative embodiment the segregated impurities region 60 is about an atomic monolayer thick, which monolayer itself may not be fully occupied by the impurities. The way to characterize the amount of impurities present at the interface 69 is by giving their area, or two-dimensional, density. In representative embodiments of the invention such area densities of the segregated impurities are between about 1×10¹³/cm² and 1×10¹⁵/cm².

The impurities are segregated onto the interface between a silicide and a semiconductor, and are present at the contact 70 of the channel 40 and the first terminal 20. Therefore, they have a determining influence on the workfunction of the silicide, and thus, the resistance of the contact. Consequently, properly chosen impurities segregated in the Schottky contact determine the resistance of the contact, and can lower this resistance in comparison to an identical contact which is without the segregated impurities.

It has been observed that silicon substitutional impurities are well suited for the purposes of both segregation on the interface and to affect the workfunction of the silicide. In exemplary embodiments of NMOS devices, where the carriers in the channel 40 are electrons, one would introduce into the interface “group V” elements such as P, As, and Sb, all of them well know in the art as n-type dopants for Si based materials. In exemplary embodiments of PMOS devices, where the carriers in the channel 40 are holes, one would introduce into the interface “group III” elements such as B, Al, Ga, and In, all of them well know in the art as p-type dopants of Si based materials. Depending on the particular embodiment, the impurities can be selected in any predetermined proportion for optimizing their contact resistance lowering effect between the channel 40 and the first terminal 20. In a SOI MOSFET device having a Schottky contact with segregated impurities at the interface the total parasitic resistance can be low enough for avoiding the imperfect and difficult process of fabricating a raised source/drain.

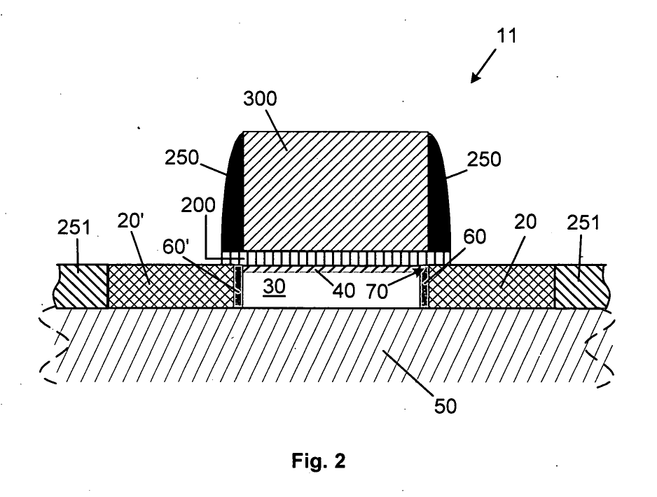

FIG. 2 shows a schematic cross sectional view of a SOI MOSFET device 11 with Schottky contacts to the channel, and shows the impurity segregation. This figure shows schematically and conceptually a completed SOI MOSFET, which in an exemplary embodiment is a fully depleted ultra thin SOI MOSFET. The device 11 of FIG. 2 has the same first terminal structure as depicted in more detail in FIG. 1. FIG. 2 also shows a second terminal 20′ formed of a second silicide material. On the interface of the second terminal segregated impurities 60′ are determining the resistance of the Schottky contact between the second silicide material of the second terminal 20′ and the channel 40. In a typical embodiment the first terminal and the second terminal are formed in the same manner, and the first and second silicide materials of the first terminal and second terminal, 20 and 20′, respectively, are materials of the same kind, for instance, both can be nickel silicide. Also, the segregated impurities at the first terminal interface 60 and second terminal interface 60′ can be impurities of the same kind, for instance Sb. Discussions regarding a second terminal structure should not be read in limiting fashion, since for some embodiments of the invention the second terminal does not necessarily have to be composed of a silicide material, or have segregated impurities at the Schottky contact.

There are many variations possible on the device shown in FIG. 2, as they would be clear to one skilled in the art. For instance, the spacers 250, may or may not be present in the device, or regions isolating the devices from each other 251 can take many different forms. How the position of the Schottky contact and the segregated impurities are spaced in relation to the gate edge are also a matter of choice for any particular device design. These, and many other aspects, as well, that have to be carefully selected for particular embodiments, as best suited to a specific application. In each case, however, the contact between the channel 40 and the first terminal 20 is a Schottky contact, and segregated impurities 60 are present on the interface of this Schottky contact 70.

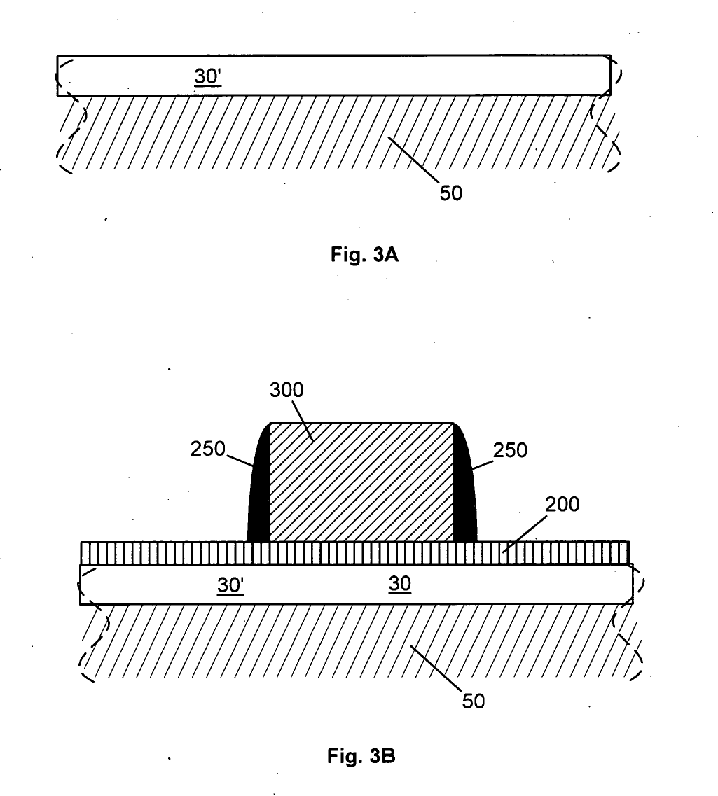

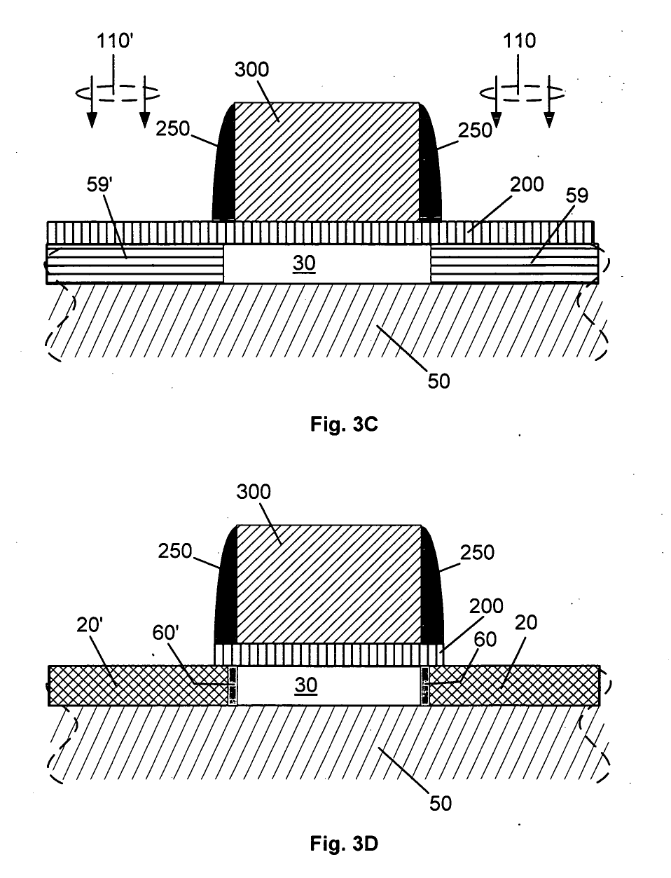

FIGS. 3A-3D schematically show a series of steps in the method of forming the Schottky contact SOI MOSFET. FIG. 3A shows an initial stage of the fabrication which may start by providing a layer composed of a crystalline Si based material 30′, which layer is disposed over an insulator 50. In a typical embodiment the Si based material 30′ is essentially Si, and the layer 30′ and insulator 50 are part of a SOI substrate, ready to fabricate ultra thin SOI devices. Upon having completed the fabrication, a portion, or region, of the crystalline Si based material 30′ will become the body 30, while other regions of layer 30′ will be turned into the source and drain terminal-regions.

FIG. 3B shows an intermediate stage in the process, when a gate 300, a gate insulator 200, and spacers 250, are already in place, and thereby defining in the layer 30′ a body region 30, which is under the gate 300. Again, there are a large number of possible variations regarding the details of a particular process, with such variations being know in the art. For instance, gate insulator 200 may not be present over all regions, the spacer 250 may or may not be present at this stage, or made use of at all. Also, by this stage some impurities may have already been introduced into the first terminal and second terminal-regions. All of these scenarios, and many possible others, are within the scope of the step of forming the body.

FIG. 3C shows the definition of a first terminal-region in the layer adjoining the body 30, and the introduction of impurities into the first terminal-region. In an exemplary embodiment the introduction of the impurities follows the step of body fabrication, but in alternate embodiments one might have a different sequence of steps. The sequence of steps depicted in FIGS. 3A-3D are not to be interpreted as a limitation.

In a typical embodiment the introduction of impurities is done by ion implantation 110. The density of the introduced impurities 59 in the first terminal-region is typically between about 5×10¹⁷/cm³ and 5×10²⁰/cm³. The introduced impurities 59 can be chosen to comprise silicon substitutional impurities. They may be selected in a predetermined proportion from the group of P, As, Sb for NMOS devices, and from the group of Al, B, Ga, In for PMOS devices. The second terminal-region may also have impurities 59′, and in a representative embodiment these are introduced by ion implantation 110′. In an exemplary embodiment the source and the drain region have the same kind of impurities, introduced in the same dose, and with the same process, such as ion implantation.

FIG. 3D shows the processing stage after having formed the first terminal 20. In the region of the first terminal essentially all of the Si based material of layer 30′ has been converted into the first silicide material, by one of the methods known in the art. In such a process an interface is being created between the first silicide material and the body 30, with a Schottky contact being formed at the interface between the channel 40 and the first terminal 20. As the silicidation advances through the Si based layer 30′, a fraction of the introduced impurities 59 segregate onto the interface 60. This segregation is due to the so called silicidation induced impurity segregation. Details of the silicidation induced impurity segregation process are given in the already quoted publication of Jakub Kedzierski et al,: “Threshold voltage control in NiSi-gated MOSFETs through silicidation induced impurity segregation (SIIS)”, IEEE Transaction on Electron Devices, 2005. Finally, when the silicidation is completed, to a large extent the segregated impurities will determine the resistance of the Schottky contact.

In an exemplary embodiment the region of the second terminal is also converted into a second terminal 20′ by siliciding the Si based layer 30′. A fraction of the introduced impurities 59′ will segregate to the interface 60′ of the second terminal with the body. In a representative embodiment the source and the drain are composed of the same silicide material, and have the same kind of impurities segregated on their respective interfaces with the body. Typically, a variety of processing parameters are so selected that the body 30 is in a fully depleted state. The first terminal, and possibly the second terminal as well, have their respective silicide materials penetrating all the way to the insulating layer 50, consuming the Si based material layer 30′ originally present in those regions. Following the stage shown in FIG. 3D the processing of the SOI MOSFET device can follow paths known in the art.

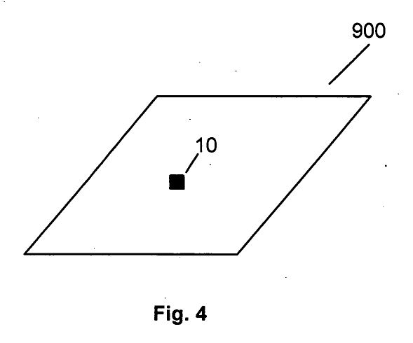

FIG. 4 symbolically shows a processor 900 which contains a MOSFET device 10 with a Schottky contact between a silicided terminal and the channel, and having a plurality of segregated impurities on the terminal/semiconductor interface.

Many modifications and variations of the present invention are possible in light of the above teachings, and could be apparent for those skilled in the art. The scope of the invention is defined by the appended claims.

We claim:

1. A MOSFET device, comprising:
a body composed of a crystalline Si based material, said body having two opposite sides: a top side, and a bottom side, wherein said body is disposed over an insulator with said bottom side interfacing with said insulator, wherein said body is hosting a channel extending from said top side;
a first terminal adjoining said body, said first terminal is composed of a first silicide material, said first terminal has an interface with said body and forms a Schottky contact with said channel at said interface, said first terminal interfaces with said insulator whereby excluding said crystalline Si based material therebetween said first terminal and said insulator, said Schottky contact has a resistance; and
a plurality of segregated impurities on said interface, wherein said segregated impurities determine said resistance of said Schottky contact.

2. The device of claim 1, wherein an area density of said segregated impurities on said interface is between about 1×10¹³/cm² and 1×10¹⁵/cm².

3. The device of claim 2, wherein said segregated impurities are silicon substitutional impurities.

4. The device of claim 3, wherein said segregated impurities are selected in a predetermined proportion from the group consisting of Al, P, B, As, Ga, Sb, and In.

5. The device of claim 1, wherein said first silicide material is selected from the group consisting of nickel silicide, cobalt silicide, palladium silicide, platinum silicide, titanium silicide, and mixtures thereof.

6. The device of claim 1, wherein said body is in a fully depleted state.

7. The device of claim 1, further comprising a second terminal adjoining said body, wherein said second terminal comprises a second silicide material.

8. The device of claim 7, wherein said first and second silicide materials are of the same kind.

9. The device of claim 1, wherein said crystalline Si based material is essentially Si.

10. A method for fabricating a MOSFET device, comprising:
providing a layer composed of a crystalline Si based material, wherein said layer is disposed over an insulator;
forming a body in said layer, wherein said body is hosting a channel;
defining a first terminal-region in said layer adjoining said body, and introducing impurities into said first terminal-region;
forming a first terminal by converting essentially all of said Si based material of said layer in said first terminal-region into a first silicide material, wherein an interface is created between said first terminal and said body forming a Schottky contact at said interface between said channel and said first terminal, and wherein a fraction of said impurities segregate onto said interface and determine a resistance for said Schottky contact.

11. The method of claim 10, further comprises selecting a concentration of said impurities in said first terminal-region to be between about 5×10⁷/cm³ and 5×10²⁰/cm³.

12. The method of claim 11, wherein introducing impurities into said first terminal-region further comprise ion implanting said impurities.

13. The method of claim 11, further comprises selecting said impurities in said first terminal-region to be silicon substitutional impurities.

14. The method of claim 13, further comprises selecting said impurities in a predetermined proportion from the group consisting of Al, P, B, As, Ga, Sb, and In.

15. The method of claim 10, further comprises selecting said first silicide material from the group consisting of nickel silicide, cobalt silicide, palladium silicide, platinum silicide, titanium silicide, and mixtures thereof.

16. The method of claim 10, further comprises forming a second terminal adjoining said body, wherein said second terminal is comprising a second silicide material.

17. The method of claim 16, further comprises selecting said first and second silicide materials to be of the same kind.

18. The method of claim 10, further comprises selecting said layer to be between 1.5 nm and 120 nm thick.

19. The method of claim 10, further comprises selecting said Si based material to be essentially Si.

20. A processor comprising MOSFET devices, wherein at least one of said MOSFET devices comprises:
a body composed of a crystalline Si based material, said body having two opposite sides: a top side, and a bottom side, wherein said body is disposed over an insulator with said bottom side interfacing with said insulator, wherein said body is hosting a channel extending from said top side;
a first terminal adjoining said body, said first terminal is composed of a first silicide material, said first terminal has an interface with said body and forms a Schottky contact with said channel at said interface, said first terminal interfaces with said insulator whereby excluding said crystalline Si based material therebetween said first terminal and said insulator, said Schottky contact has a resistance; and
a plurality of segregated impurities on said interface, wherein said segregated impurities determine said resistance of said Schottky contact.
